(19) United States
(12) Patent Application Publication
(10) Pub. No.: US 2008/0210550 A1
(43) Pub. Date: Sep. 4, 2008

(54) Vacuum Coating System and Method for Vacuum Coating

(75) Inventors: Marten Walther, Alfeld (DE); Tobias Kalber, Mainz (DE); Stefan Bauer, Alzey (DE); Hartmut Bauch, Weilrod-Winden (DE); Jorn Gerban, Budenheim (DE)

Correspondence Address: DeMont & Breyer, LLC, 100 Commons Way, Ste. 250, Holmdel, NJ, 07733, US

(73) Assignee: SCHOTT AG, 55122 Mainz (DE)

(21) Appl. No.: 11/572,255

(22) PCT Filed: Jul. 8, 2005
(86) PCT No.: PCT/EP2005/007418

§ 371 Date: Sep. 8, 2007

(30) Foreign Application Priority Data
Jul. 26, 2004 (DE) 10 2004 036 170.3

(51) Int. Cl. C23C 8/00; C23C 14/00

(52) U.S. Cl. 204/192.15; 427/585; 204/298.25

(57) ABSTRACT

The invention provides a device for the vacuum coating of substrates which comprises a vacuum chamber, an apparatus for holding at least one substrate, at least one first coating region of the vacuum chamber with an apparatus for plasma pulse-induced chemical vapor deposition (PICVD) and at least one second coating region of the vacuum chamber with at least one apparatus for sputter coating, as well as a transport apparatus for transporting the substrate into the coating regions.

The invention relates generally to the field of vacuum coating or vacuum deposition on substrates, and in particular the invention relates to a vacuum coating system and a method for vacuum coating.

Various methods for vacuum deposition are known, for instance physical and chemical vapor deposition. The selection of the deposition method for coating a substrate depends inter alia on which materials are intended to be deposited. Generally, not all deposition methods in particular are equally well-suited for a particular layer composition. For example, layers with a low vapor pressure cannot or can only poorly be applied by evaporation coating. On the other hand, because of shielding effects it may be problematic to apply electrically conductive layers by means of plasma-induced chemical vapor deposition.

WO 00/52221 discloses a device and a method for the simultaneous PVD and CVD coating of elongate substrates. The elongate substrate, for example a fabric or a film, is guided through coating stations for PVD and CVD coating, the regions of the substrate which respectively lie in a coating station being coated simultaneously. The coating stations are separated from one another spatially and using vacuum technology by barriers with openings for the substrate.

Such a method, however, is not possible for many substrates owing to their small dimensions.

Furthermore, it may be desirable to apply different layers successively. Especially for particular combinations of PVD and CVD processes, it may be advantageous or even necessary to operate PVD and CVD coating sequentially, so that the processes cannot interfere with one another. For instance, an atmosphere containing oxygen for CVD coating may lead to undesired oxidation of the target material for a sputter process, if the target surface is not protected sufficiently.

It is an object of the invention to improve vacuum deposition using various deposition methods. This object is directly achieved in a very surprisingly simple way by a device and a method according to the independent claims. Advantageous configurations and refinements are given in the dependent claims.

Accordingly, the invention relates to a device for the vacuum coating of substrates which comprises a vacuum chamber, an apparatus for holding at least one substrate, at least one first coating region of the vacuum chamber with an apparatus for plasma pulse-induced chemical vapor deposition (PICVD) and at least one second coating region of the vacuum chamber with at least one apparatus for sputter coating, as well as a transport apparatus for transporting the substrate into the coating regions.

In a method for the vacuum coating of substrates according to the invention, which may in particular be carried out with a vacuum coating device according to the invention, at least one substrate is held in a vacuum chamber, at least one level of a coating is deposited on the substrate by means of plasma pulse-induced chemical vapor deposition (PICVD) in at least one first coating region of the vacuum chamber and at least one level of the coating is deposited by sputtering in a second coating region of the vacuum chamber, and the substrate is transported into the coating regions by means of a transport apparatus.

All conventional methods may be used for the sputtering. In particular, magnetron sputter apparatuses are envisaged owing to the comparatively high deposition rates. It is nevertheless also possible to use other methods, for example electron cyclotron resonance sputtering (ECR sputtering) or ion beam sputtering.

The term coating region in the context of the invention is intended to mean a region in the vacuum chamber where a substrate arranged there can be coated. In PICVD coating, in particular, the plasma for the vacuum deposition is generated in the coating region.

In particular, the substrate may be arranged sequentially in the coating regions by means of the transport apparatus, and at least one level of the coating may respectively be deposited in the coating regions in order to generate multi level coatings.

Owing to the combination of PICVD coating and sputter coating according to the invention within one coating system, it is now for the first time possible to deposit coatings which otherwise could be produced at best only in separate systems, which under certain circumstances then also leads to oxidation or other reaction with atmospheric components. With only minor thermal loading of the substrate, the PICVD method furthermore allows high radiation powers for generating the plasma since a high radiation power is delivered only during the pulse duration. In this way, according to the invention, it is also possible to produce novel coated substrates whose coatings comprise at least one sputtered level as well as at least one PICVD-coated level. Not only can such products be produced more economically and more rapidly by using the invention, but such products also have a better quality owing to the in-situ combination of these methods without contact with the atmosphere, especially in respect of lower extrinsic contamination of the coating.

In order to increase the economic viability of the method according to the invention, it is also expedient to provide a transport apparatus for simultaneously transporting a plurality of substrates. The substrates can thus be arranged on the transport apparatus and coated successively or simultaneously. Such an arrangement is also appropriate for laboratory or test operation, since the substrates do not all have to be provided with the same coating. Rather, different types of coatings can thereby be deposited without input or output processes, and for example a measurement or test series can thus be carried out.

In order to produce particular layers, it may on the other hand also be desirable to induce a controlled reaction during the sputter coating. According to one refinement of the invention, the sputtering may also comprise reactive sputtering or the sputter coating apparatus may comprise a reactive sputtering apparatus.

Particularly oxide and/or nitride layers may in this case be generated by introducing oxygen and/or nitrogen into the reaction chamber, in order to induce a reaction of the deposited layer with the atmosphere containing oxygen and/or nitrogen in the chamber. According to one refinement of the invention, for example, this may respectively be carried out while a layer is being sputtered without thereby leading to target poisoning, a plasma containing oxygen and/or nitrogen for sputtering the target being generated according to the gas constituents. This gas may, for example, be introduced in the first coating region by means of a gas supply for the PICVD coating apparatus.

A further possibility for converting a coating by controlled reaction is to nitride or oxidize at least one deposited level of the coating in the vacuum chamber by means of a plasma containing oxygen or nitrogen. According to one embodiment of the device according to the invention, to this end an apparatus for generating a plasma containing nitrogen and/or oxygen is provided. In particular, the PICVD coating apparatus or the sputter coating apparatus may also be designed for generating such a plasma, so that the apparatus for generating a plasma containing nitrogen and/or oxygen is a component of at least one of these apparatuses. According to one embodiment of the invention in this case, a level of a coating is sputtered onto the substrate in at least one first coating region of the vacuum chamber, the substrate is arranged in a second coating region by the transport apparatus and is oxidized or nitrided there by means of a plasma containing oxygen or nitrogen, in order to produce oxide and/or nitride layers. In order to generate larger layer thicknesses of such oxide and/or nitride layers, this process may also be carried out several times by repeatedly transporting the substrate between the coating regions.

A plasma generated by the PICVD coating apparatus or the sputter coating apparatus may also advantageously be used to activate or clean the substrate surface by means of a plasma. For example, a plasma containing oxygen and/or nitrogen may also be used to this end. Activation is favorable inter alia for plastic substrates, such as PMMA substrates, in order to improve the adhesion of subsequently applied layers. In general, the activation and/or cleaning may be carried out as a pretreatment, intermediate treatment or post-treatment step.

According to yet another embodiment of the invention, the device comprises one or more apparatuses for rotating the substrate. Rotation of the substrate by the transport apparatus may, for example, be used to move the substrate into the coating regions on a circular transport path. In particular, the coating regions may in this case be arranged along the circumferential direction of a circular section of the transport path of the transport apparatus, so that the substrates are moved by the rotation along the transport path through the coating regions, and are arranged and coated in front of the coating apparatuses. It may furthermore be advantageous to rotate the substrate about a plurality of axes by means of a corresponding apparatus. The term transport path in the context of the invention is intended to mean the route along which the substrates or substrate holders are moved in the vacuum chamber.

According to a further embodiment of the invention, the movements of a plurality of substrates are driven independently of one another, in order to permit a flexible and adaptable coating process. To this end, the transport apparatus may advantageously comprise a plurality of apparatuses for moving substrates, which can be driven independently of one another.

According to yet another embodiment of the invention, the substrate is moved linearly in the vacuum chamber by means of a correspondingly designed transport apparatus. A linear movement of the substrate may of course also be combined with a circular movement of the substrate, for instance if the transport path comprises linear and circular sections or the substrate is guided linearly on rotatable holders. In conjunction with a linear movement of the substrate, according to one refinement it is also expedient for at least one of the apparatuses for plasma pulse-induced chemical vapor deposition (PICVD) or the apparatuses for sputter coating to be arranged along at least one linear section of the transport path of the transport apparatus, so that the substrates enter the individual coating regions during the transport.

According to one advantageous refinement of the method according to the invention, in particular, the substrate is moved during the coating. This is appropriate particularly in order to produce uniform coatings, since inhomogeneities of the sputter or PICVD plasma coating can be averaged out by moving the substrate.

Besides delivering the substrates, the transport apparatus may also have further functions. For example, the transport apparatus may also be used to separate the coating regions. This is appropriate inter alia in order to sustain a pressure gradient in the vacuum chamber and/or to achieve electromagnetic shielding. According to one refinement of the invention, such separation of the coating region may be achieved in that the transport apparatus comprises a substrate holder which is arranged between opposing apparatuses for plasma pulse-induced chemical vapor deposition (PICVD) and for sputter coating.

According to yet another refinement of the invention, there may also be a screen device for screening the sputter target. The sputter target can thereby be screened during plasma pulse-induced chemical vapor deposition or during a cleaning procedure in order to remove water or, for example, an oxide layer on the substrate, so as to prevent contamination of the sputter target. At the same time the screen device is used in order to protect the substrate surface during sputtering in the closed position, i.e. lying in front of the target surface as a deposition surface of oxidized/nitrided target material-particularly during cleaning of the target.

In order to increase the throughput and improve the economic viability, according to yet another refinement of the invention a plurality of substrates may be coated in parallel or sequentially with at least one level of the coating. The plurality of substrates may, for example, be arranged together in a coating region. There may also be a plurality of apparatuses for plasma pulse-induced chemical vapor deposition (PICVD) and/or a plurality of apparatuses for sputter coating. The apparatuses may in this case also be operated at least partially in parallel so that, for example, a level of a coating is respectively deposited in parallel on one or more substrates arranged in the assigned coating region by each of the simultaneously operated coating apparatuses. For example, the substrates may also be moved through the respective coating regions of the apparatuses while respectively depositing a particular level so as to create a multi level coating.

Both when sputtering and for PICVD coatings, process gas is used for the respective plasma. In order to discharge the quantities of gas incurred in this case, it is advantageous to provide a high-performance pump system. The performance capability of a pump system is determined inter alia by the cross section and the position of the connection of the vacuum chamber to the pump system. According to one embodiment of the invention, a pump apparatus is used with a plurality of connections to the vacuum chamber. In particular, according to one refinement of this embodiment, at least one connection may be assigned to each coating region. For example, the pumps connected to the connections may be dimensioned in respect of their pump power according to the quantities of gas incurred during the various types of coating, in order to obtain an optimal extraction pumping power with minimal outlay. According to yet another embodiment of the invention, at least one apparatus for applying a coating by evaporation is additionally provided. Through the possibility of depositing a layer by evaporation, the versatility of the applicable layer systems can be increased further.

By combining PICVD coating and sputter coating in a coating chamber, the method according to the invention or the device according to the invention for vacuum coating is suitable for producing a multiplicity of different coatings for substrates, for example for depositing a multi level coating with levels of different composition, alternating multi level layers with alternating composition, coating with a deposited adhesion promoter layer and/or a gradient layer. At least one metallic and/or magnetic layer may be deposited by the sputtering and, for example, combined with one or more PICVD levels of the coating. A favorable application is inter alia the sputter coating of plastic substrates. Plastic often cannot be coated well with durable layers by sputtering. According to the invention, however, an adhesion promoter layer on which the sputtered layer adheres well may be deposited by PICVD.

The application fields and the function of layers produced according to the invention are correspondingly widespread. For example, PICVD coating can be used to produce barrier layers which protect underlying layers, for instance a sputtered metal layer, against degradation, particularly oxidation. Coatings with scratch proof and/or nonstick properties may also be deposited. Coatings with optical functions are a wide field, for example blooming layers or interference filter layers which may be applied according to the invention.

The method is also highly suitable for producing electrically conductive transparent layers, which may then also be protected by one or more further layers. Such layers may also be applied onto an adhesion promoter layer deposited according to the invention in particular by means of PICVD, in order to improve the adhesion. Inter alia, the deposition of an indium tin oxide layer may be envisaged in this case. Inter alia displays, such as for a mobile telephone or particularly a PDA (“portable digital assistant” or Palm computer) or a touch-screen, are one application of such coatings. Especially in a PDA or a touch-screen, information for the information processing system is input by touching the display, so that scratch proof protection on the display is advantageous for the service life.

Layers containing zirconium, niobium or tantalum, for example their oxides or nitrides or alloys with these materials, can also generally be produced only with difficulty by PICVD. By means of the invention, however, such coatings can be sputtered and optionally combined advantageously with PICVD coatings.

According to yet another refinement of the invention, at least one level of the layer is deposited by means of electron cyclotron resonance sputtering (ECR sputtering). Layers which are applied by this deposition method are often distinguished by a particularly high density and freedom from defects. In order to produce such layers, the device according to the invention may comprise an apparatus for electron cyclotron resonance sputtering, to which end the sputter coating apparatus may have its design adapted accordingly and/or the electron cyclotron resonance sputtering apparatus may be provided in addition to the apparatuses for plasma pulse-induced chemical vapor deposition (PICVD) and sputter coating.

According to another advantageous refinement of the method according to the invention, at least parts of the vacuum chamber or the substrate are heated. To this end, the device may additionally comprise a heating apparatus. Heating the chamber may, for example, be advantageous in order to prevent precipitation of process gas constituents in the chamber. Furthermore, heating the substrate may be advantageous when sputtering layers, for example in order to produce particularly dense layers.

The invention will be explained in more detail below with the aid of exemplary embodiments and with reference to the drawings, identical and similar elements being provided with the same references and the features of various exemplary embodiments being combinable with one another.

FIG. 1 shows a schematic plan view of a device for the vacuum coating of substrates according to a first embodiment of the invention,

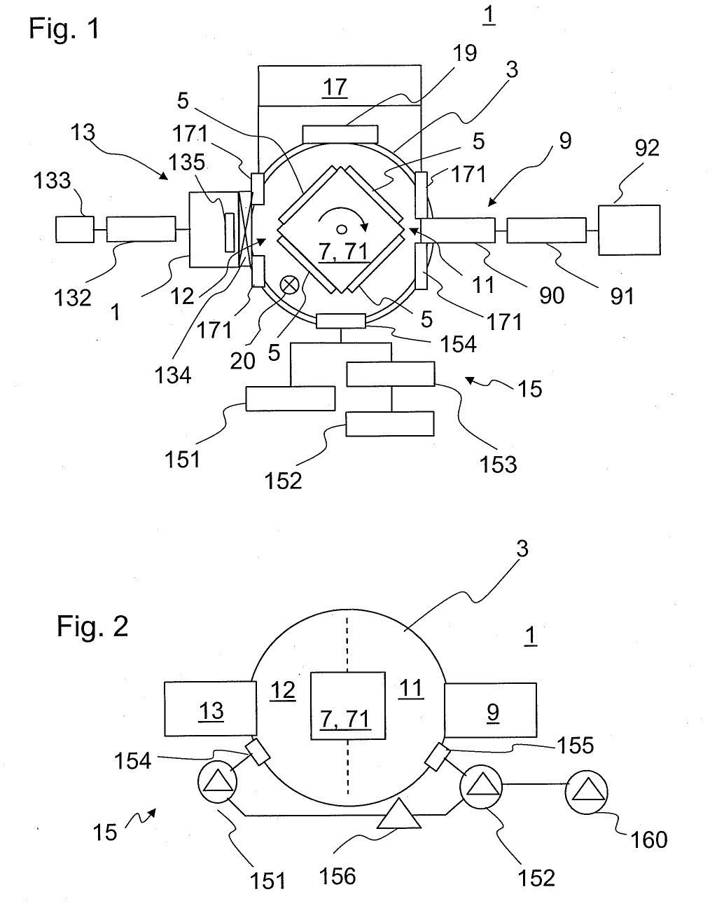

FIG. 2 shows a schematic representation of a coating device with a variant of the pump apparatus shown in FIG. 1,

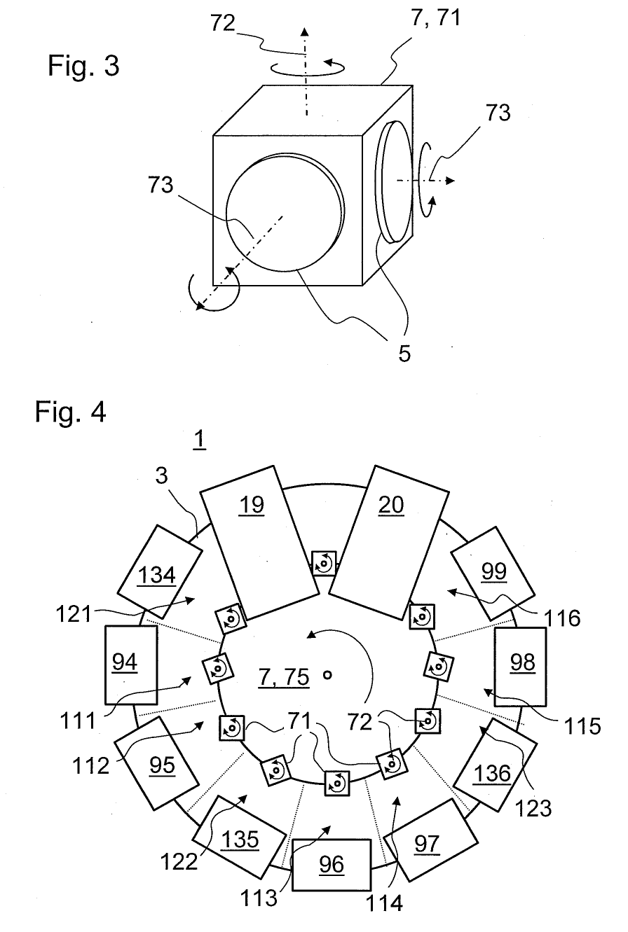

FIG. 3 shows an embodiment of a substrate holder of a transport apparatus,

FIG. 4 shows a further embodiment of a device according to the invention for the vacuum coating of substrates,

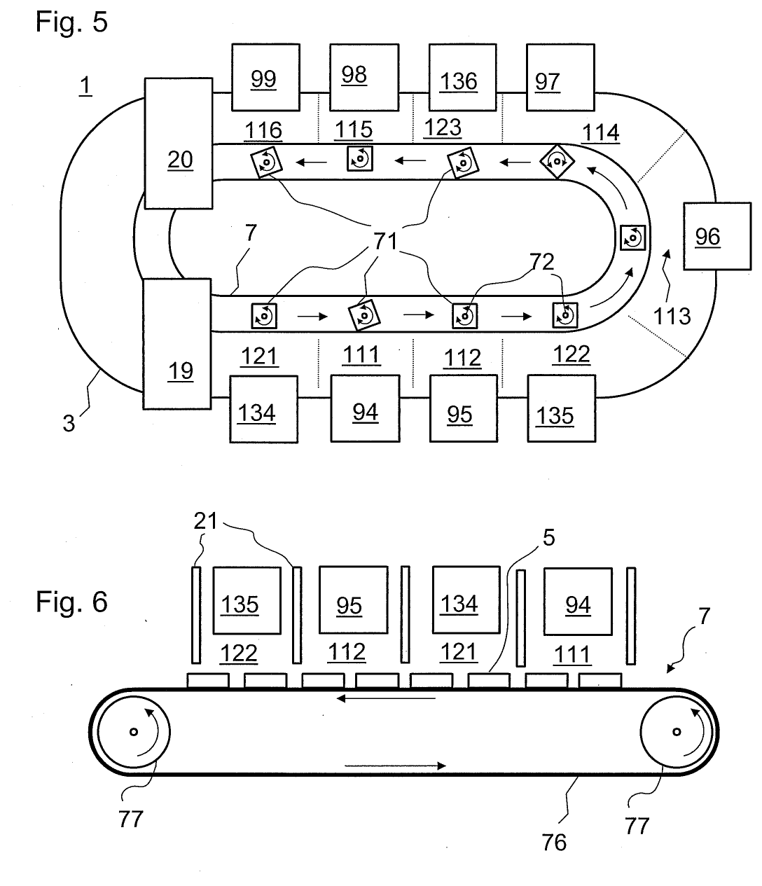

FIG. 5 shows a variant of the embodiment represented in FIG. 4,

FIG. 6 shows parts of another embodiment of a device according to the invention having a transport apparatus with a conveyor belt,

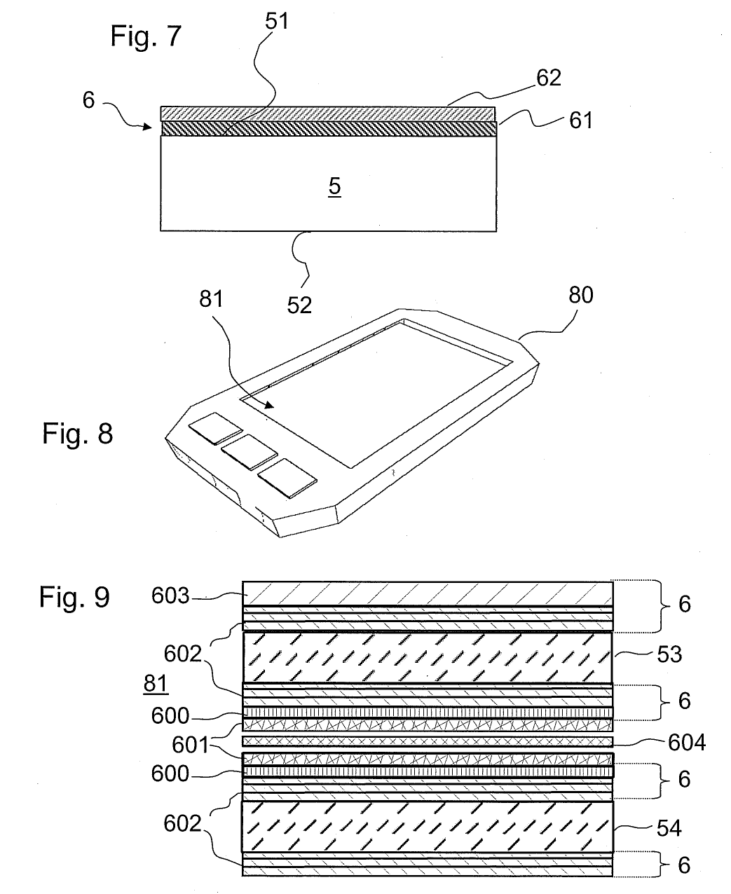

FIG. 7 shows an embodiment of a substrate coated according to the invention,

FIG. 8 shows a PDA with a display panel coated according to the invention,

FIG. 9 shows a cross section through a display panel coated according to the invention.

FIG. 1 shows a schematic plan view of a first embodiment of a device according to the invention, denoted overall by the reference 1, for the vacuum coating of substrates.

The device 1 comprises a vacuum chamber 3, in which a transport apparatus 7 is arranged for transporting substrates 5 into coating regions 11, 12 of the vacuum chamber 3. The device 1 furthermore comprises a plasma pulse-induced chemical vapor deposition (PICVD) apparatus 9 assigned to the coating region 11 and a sputter coating apparatus 13 assigned to the coating region 12.

In the embodiment represented in FIG. 1, the transport apparatus 7 comprises a rotatable substrate holder 71, on which a plurality of substrates 5—for example four substrates 5 in the device shown in FIG. 1—can be arranged, simultaneously transported by rotation and coated successively or even in certain cases simultaneously. By rotating the substrates 5 on the transport apparatus 7, or its substrate holder 71, the substrates 5 can respectively be transported into the coating regions 11, 12 for depositing a PICVD or sputter layer. Owing to this arrangement, this exemplary embodiment comprises a circular transport path along which the coating regions 11, 12 are arranged.

In the embodiment shown in FIG. 1, the substrate holder 71 of the transport apparatus 7 is furthermore arranged between opposing apparatuses 9, 13 for plasma pulse-induced chemical vapor deposition (PICVD) and sputter coating. This achieves a certain degree of separation between the coating regions 11, 12 and the coating apparatuses 9, 13. At least partial electromagnetic shielding and/or a pressure barrier between the coating regions 11, 12 are obtained in this way.

In order to provide the process and sputter gases, there is a gas supply 17 which is connected to gas inlets 171 at the coating regions 11, 12. A suitable process or sputter gas can then respectively be introduced by the gas inlets 171 into the coating regions 11, 12 in order to generate a plasma for the PICVD deposition or the cathodic sputtering of a target for sputter coating a substrate 5.

Besides the assigned gas inlets 171, the sputter coating apparatus 13 comprises a sputter magnetron 131, a high-voltage power supply unit 133 for supplying the sputter magnetron 131, an arc discharge suppression apparatus 132 connected between the power supply unit 133 and the magnetron 131, and a sputter target 135. In this exemplary embodiment of the invention, a screen device 134 is additionally provided for selectively screening the sputter target 135. Temporary screening of the target is advantageous in particular to avoid contamination during particular treatment steps of the substrate or substrates 5 to be coated. For example, the sputter target 135 may be screened during plasma pulse-induced chemical vapor deposition or during a cleaning procedure to remove water or an oxide layer on the substrate 5, in order to avoid precipitation of a PICVD coating or water or oxides coming from the substrate. Conversely, substrates located in the chamber may be protected against precipitation of sputtered material during a procedure of cleaning the sputter target. Besides the usual noble gases, by means of the gas supply additional gases for reactive sputter coating may also be mixed with the sputter gas delivered via the gas inlets 171. Such gases, particularly nitrogen and/or oxygen, may also be introduced via the gas inlets 171 of the PICVD coating apparatus 9. With these gas constituents, a plasma containing oxygen and/or nitrogen is then formed during the sputter coating. For example, reactive radicals of these gases are then formed in the plasma, which lead to oxidation or nitriding of the layer constituents.

Besides the gas inlets 171 for introducing the process gas, the PICVD coating apparatus 9 comprises an antenna 90 for supplying the electromagnetic radiation to ignite the plasma and a generator 92 for generating pulsed electromagnetic energy. A tuning unit 91, with which the input of radiation into the coating region 11 can be adjusted and optimized, is also provided between the antenna 90 and the generator 92. The generator 92 may, for example, be configured to generate microwaves. A microwave frequency of 2.45 GHz is preferably used for the PICVD coating.

The plasma pulse-induced chemical vapor deposition apparatus 9 may also fulfill functions other than the deposition of a PICVD layer. According to one embodiment of the invention, instance, an apparatus for generating a plasma containing nitrogen and/or oxygen is provided. The plasma pulse-induced chemical vapor deposition apparatus 9 may in this case be used as such an apparatus for generating a plasma containing nitrogen and/or oxygen, by introducing gas containing oxygen and/or nitrogen through the gas inlets 171 and generating a plasma containing oxygen and/or nitrogen in the coating region 11 during operation of the generator 92. In this way, oxide and/or nitride layers can be deposited on the substrate 5 by sputtering a level of a coating onto the substrate 5 in the coating region 12 of the vacuum chamber 3, arranging the substrate 5 in the coating region 11 by the transport apparatus 7 and oxidizing or nitriding the plasma containing oxygen or nitrogen there. This procedure may in particular also be repeated several times in order to generate the thicker oxide and/or nitride layers.

Such a plasma containing nitrogen and/or oxygen may also be used to activate and/or clean the substrate surface as a pretreatment and/or intermediate treatment and/or post-treatment step during the coating of the substrate according to the invention.

In order to evacuate the vacuum chamber and discharge the process gas, a pump apparatus 15 with a high vacuum pump apparatus 151 and a fine vacuum pump apparatus 152 is provided.

In order to regulate the process pressure during the PICVD process, a pressure regulator 153 is also provided. The pump apparatus 15 is connected to the chamber 3 via a connection 154.

In order to load and unload the substrates 5, a loading apparatus 19 is furthermore provided. In the simplest case, the loading apparatus 19 may comprise a loading door through which the substrates can be fitted from the outside and removed.

A heating apparatus 20 is furthermore provided, with which the vacuum chamber 3 can be heated. This is advantageous, for example during PICVD coating, in order to prevent precipitation of process gas constituents, in particular coating precursors. The substrate holder 7 may also comprise a heating apparatus, with which the substrate 5 can be heated. Heating the substrate can inter alia increase the quality of layers deposited by means of sputtering.

FIG. 2 schematically represents a further embodiment of a device 1 according to the invention. In this embodiment, the pump apparatus 15 comprises a plurality of connections 154, 155 to the vacuum chamber 3. The connection 154 is connected to a high vacuum pump apparatus 151 and the connection 155 is connected to a fine vacuum pump apparatus 152. The high vacuum pump apparatus 151 is connected to a pre-pressure pump apparatus 160 via the fine vacuum pump apparatus 152 as an additional pressure stage, in which case the high and fine vacuum pump apparatuses 151, 152 may be separated from one another by a valve 156.

The connections 154, 155 to the variously configured pump apparatuses are, in particular, assigned to the different coating regions 11, 12. Since different gas pressures are generally used during the coating methods and a pressure gradient between the regions 11, 12 may therefore be set up in the chamber, separately connecting the coating regions to the pump apparatus 15 ensures particularly effective and rapid evacuation so that the process or sputter gas intended for a further coating step can be rapidly introduced again after a coating step.

FIG. 3 shows a refinement of the transport apparatus shown in FIG. 1 with a substrate holder 7. The exemplary embodiment of a transport apparatus 7 as shown in FIG. 2 likewise comprises a substrate holder 71 for holding a plurality of substrates 5. In order to transport the substrates 5 into the individual coating regions, the substrate holder 71 is rotatable about an axis 72 so that the substrates 5 can be delivered along a circular transport path as in the case of the device 1 shown in FIG. 1. The substrates 5 are also respectively rotatable about axes 73, the axes 73 in the example shown in FIG. 22 being perpendicular to the rotation axis 72. For example, a substrate 5 may be moved about one or both axes 72, 73 during coating in the plasma, in order to average out inhomogeneities of the plasma and therefore achieve uniform coating.

FIG. 4 shows yet another embodiment of a device 1 according to the invention for the vacuum coating of substrates. The transport apparatus 7 of this embodiment of the invention comprises a carousel, on which a plurality of substrate holders 71 can be arranged. Using the carousel, the substrate holders 71 with the substrates (not represented in FIG. 4 for the sake of clarity) are delivered along a circular transport path. The substrate holders 71 may, for example, be constructed according to the exemplary embodiment shown in FIG. 4. In the embodiment of the device 1 as shown in FIG. 4, the movements of the substrates may in particular be driven independently of one another. To this end the substrate holders 71 are arranged, rotatable independently of one another, on the carousel of the transport apparatus and therefore constitute apparatuses respectively drivable independently of one another for moving the one or more fastened substrates. Using a suitable control apparatus (not shown), for example a computer-assisted controller, each of the substrate holders 71 can thus be rotated about its rotation axis 72 independently of the other holders 71 on the carousel. Accordingly, the substrates may also be rotated about a plurality of axes, i.e. the axis of the carousel and the rotation axis of the respective substrate holder. Rotation of the substrate about a further axis 73 may furthermore be provided, as is possible for example with the substrate holder 71 shown in FIG. 3.

The embodiment represented in FIG. 4 furthermore comprises a plurality of apparatuses 94, 95, 96, 97, 98, 99 for plasma pulse-induced chemical vapor deposition (PICVD) and a plurality of apparatuses 134, 135, 136 for sputter coating of the substrates. The apparatuses 94, 95, 96, 97, 98, 99 and 134, 135, 136 are arranged in the circumferential direction of the carousel 75 of the transport apparatus 7 so that the coating regions 111, 112, 113, 114, 115, 116 and 121, 122, 123 of the apparatuses 94, 95, 96, 97, 98, 99 for plasma pulse-induced chemical vapor deposition (PICVD) or the apparatuses 134, 135, 136 for sputter coating of the substrates are also arranged along the circumferential direction of the circular transport path. In particular, the arrangement of the coating regions 111-116 and 121-123 is adapted to the spacing of the substrate holders 71 on the carousel 75, so that a substrate holder with the substrates respectively lies in one of the coating regions and at least one level of the coating can be deposited. In this way, it is also possible for a plurality of substrates to be arranged on the transport apparatus and coated simultaneously. In this case, it is also feasible not to operate all of the sputter and PICVD coating apparatuses in parallel. For example, depending on the intended process sequence, they may also be operated in groups. For example, it may be expedient to operate the sputter coating apparatuses 134, 135, 136 and the PICVD coating apparatuses 94-99 respectively in groups, but successively in the generally different pressure ranges for PICVD and sputter coating.

The embodiment of the device 1 as shown in FIG. 4 allows a multiplicity of different operating modes. For example, the substrates may be arranged sequentially in the coating regions 111, 112, 113, 114, 115, 116 and 121, 122, 123 where at least one level of the coating is then respectively deposited. The substrates 5 are removed once they have passed through all the coating regions 111, 112, 113, 114, 115, 116 and 121, 122, 123. This variant of the method according to the invention may of course also be carried out with only some of the apparatuses 94-99, 134-136. The PICVD coating apparatuses may also be operated in parallel so that coating levels of the same type are deposited simultaneously on all substrates arranged in the coating regions 111-116. A similar procedure may also be adopted in the coating regions 121, 122, 123. The substrates 5 then do not need to pass through all the coating regions, rather a plurality of substrates are coated in parallel and simultaneously. For such operation-other than as represented in FIG. 4—a plurality of sputtering apparatuses may be provided likewise as for the PICVD coating apparatuses.

One or more of the sputter coating apparatuses 134, 135, 136 may also comprise an apparatus for electron cyclotron resonance sputtering, for example in order to deposit particularly dense layers by means of ECR sputtering.

Besides the loading apparatus 19, a separate unloading apparatus is also provided in this embodiment in order to permit a continuous production sequence.

FIG. 5 shows a variant of the embodiment represented in FIG. 4. Similarly as the device outlined in FIG. 4 for the vacuum coating of substrates, the embodiment represented in FIG. 5 also comprises a plurality of apparatuses 94, 95, 96, 97, 98, 99 for plasma pulse-induced chemical vapor deposition and a plurality of apparatuses 134, 135, 136 for sputter coating of the substrates. In contrast to the embodiment shown in FIG. 4, however, the substrate holders 17 with the substrates are delivered along a racetrack-shaped transport path. Accordingly, the substrates are delivered not only along a circular section, but also a long two linear sections of the transport path to the coating regions 111, 112, 113, 114, 115, 116 and 121, 122, 123 of the apparatuses 94, 95, 96, 97, 98, 99. In the device 1 shown in FIG. 5, for example, the PICVD coating apparatuses 94, 95, 97-99 and the sputter coating apparatuses 134, 135, 136 are arranged along the linear sections of the transport path, while the PICVD coating apparatus 93 lies on a circular section.

FIG. 6 shows parts of a device 1 according to the invention with a further embodiment of a transport apparatus. The transport apparatus of this embodiment of the invention comprises a conveyor belt which is guided on rollers 77, and on which the substrates 5 are placed and delivered along a linear transport path to the coating regions 111, 121, 112, 122.

Owing to the arrangement as shown in FIG. 6, the conveyor belt 76 accordingly constitutes an apparatus for linear movement of the substrates 5. The PICVD coating apparatuses 94, 95 and the apparatuses 134, 135 in this embodiment are arranged above the conveyor belt 76 along the linear transport path. With a conveyor belt, of course, it is nevertheless also possible to achieve other forms of transport paths, for instance with linear and curved e.g. circular sections.

In order to separate the coating regions 111, 121, 112, 122 better from one another and from other regions of the vacuum chamber, barriers 21 are additionally provided to delimit the coating regions. The barriers 21 may, for example, serve to sustain a pressure gradient between the coating regions and/or for electromagnetic shielding. Such barriers 21 may also be provided in the other embodiments of devices 1 according to the invention, as represented for instance in FIGS. 1 to 5.

FIG. 7 shows a first exemplary embodiment of a substrate 5 coated according to the invention. The substrate 5 comprises two opposite sides 51, 52, of which the side 51 has been provided with a coating 6 by vacuum deposition. The coating 6 comprises two levels 61, 62, of which one of the levels has been applied by PICVD coating and the other level by sputtering. The sputtered level may also have been nitrided or oxidized by introducing nitrogen and/or oxygen into the vacuum chamber or alternatively in a plasma containing nitrogen or oxygen. Depending on the functionality of the coating, both the level 61 and the level 62 may be deposited by PICVD coating.

For example, the lower layer 61 may be a metallic layer which has been deposited by sputtering. The layer 62 may then serve as a barrier layer to protect the metallic layer against oxidation and be deposited by means of PICVD. A silicon oxide layer, which may be generated by using a process gas containing hexamethyldisiloxane (HMDSO), is for example suitable for this. A substrate with a metallic sputtered layer and a PICVD barrier coating may, for example, be used as a lamp reflector. Such an SiO₂ layer may furthermore be used as a scratch proof coating.

The sputtered layer 61 may for example also be nitrided or oxidized with the device according to the invention, before the barrier or scratch proof layer 62 is applied. To this end, the layer may be nitrided in the coating region of the PICVD coating apparatus in a plasma containing oxygen and/or nitrogen. Particularly for thin layers, it has been found that it is possible to achieve nitriding or oxidation by introducing nitrogen and/or oxygen even without igniting a plasma. For thicker layers, the process of sputtering and nitriding or oxidation may also be repeated several times. A nitrided layer 61, for instance a nitrided titanium layer, may for example be used to achieve a decorative gold effect. The sputtered layer 61 may also be a magnetic or magnetizable layer, which is then covered with a barrier layer 62 deposited by PICVD. Such coated substrates 5 may for instance be magnetic data media.

One of the layers 61, 62 may, for example, also be a sputtered layer which contains zirconium and/or niobium and/or tantalum. Applications for oxide layers of these elements are, for example, coatings with optical functionality owing to the high refractive index of the oxides.

Owing to the comparatively low thermal load during PICVD coating, plastics such as Makrolon® (PMMA) or PP, PC may also be used as the substrate 5. In this case, it is often suitable for an adhesion promoter layer, for example in the form of a gradient layer with a carbon content varying in the normal direction of the layer, to be deposited by means of PICVD before sputtering.

FIG. 8 shows a further application of the invention. FIG. 8 shows a PDA, for example a Palm computer 80. The display of the PDA 80 comprises a display panel 81 with one or more substrates 5 coated according to the invention. Besides display purposes, the display panel 81 is also used to input information similarly as in the case of a touch-screen. To this end, such a panel conventionally comprises transparent conductive layers.

A problem is that the optical properties of the display panel, for instance its transparency, may be detrimentally affected over the course of time by input with a stylus and scratching caused thereby. With the invention, however, sputtered conductive layers may for example be combined with scratch proof layers and anti reflection layers, in order to durably maintain the optical properties of such a display panel 81.

FIG. 9 shows a cross section through an embodiment of a display panel 81 coated according to the invention, with two substrates 53, 54 respectively having multi level coatings 6, as may be used particularly as a display panel for a PDA or a touch-screen.

The display panel 81 comprises two substrates 53, 54, both of which are coated according to the invention. To improve the light transmission and reduce interfering reflections, the two substrates comprise anti reflection coatings 602 on both sides in the form of alternating multi level layers deposited according to the invention. The multi level anti reflection layers may, for example, be designed as alternating silicon oxide/titanium layers. To this end, the process gas composition is changed during the PICVD coating, in which case HMDSO for the silicon oxide levels and titanium chloride (TiCl₄) for the one or more titanium oxide levels may be used as process gas constituents. Such an alternating multi level layer may also advantageously be used as a multi level interference layer for other applications, such as for an optical interference filter. Applications for such a filter are, for example, color wheels for digital projectors, dichroic mirrors or color filters for LCD projectors. Respectively on one side of the substrates 53, 54, an adhesion promoter layer 600 is furthermore deposited by means of PICVD and an indium tin oxide layer (ITO layer) 601 is deposited on top by sputtering. In order to produce a display panel 81, the two substrates 53, 54 are put together a small distance apart with the indium tin oxide layers 601 facing each other. In order to ensure spacing between the substrates, a spacer layer 604 may for example be provided between the substrates 53, 54. When pressure is applied onto the layer surface by an input stylus, the substrates 53, 54 are pressed together so that the two conductive ITO layers come in contact locally below the input stylus. The input carried out with the stylus is read by evaluating the local short circuit caused thereby.

In order to protect the input side of the display panel 81, a scratch proof coating 603 is furthermore applied on this side, preferably by means of PICVD. The scratch proof layer 603 and/or the adhesion promoter layer 600 may also advantageously be deposited as levels with a composition gradually varying perpendicularly to the layer, i.e. as gradient layers, in order to improve the adhesion of the layers to one another. With PICVD coating, for example, this is readily achievable by continuously changing the composition of the process gas. An additional adhesion promoter layer may also be deposited on the anti reflection layer 602 before depositing the scratch proof layer 603.

It is clear to the person skilled in the art that the invention is not restricted to the embodiments described above, but instead may be modified in a variety of ways. In particular, the features of the individual exemplary embodiments may also be combined with one another.

List of References

| | |
|---|---|
| 1 | device for the vacuum coating substrates |
| 3 | vacuum chamber |
| 5, 53, 54 | substrate |
| 6 | substrate coating |
| 7 | transport apparatus |
| 9, 94-99 | apparatus for PICVD coating |
| 11, 111-116, | coating regions |
| 12, | |
| 121-123 | |
| 13, 134, | apparatus for sputter coating |
| 135, 136, | |
| 15 | pump apparatus |
| 17 | gas supply apparatus |
| 19 | loading apparatus |
| 20 | heating apparatus |
| 21 | barrier |
| 51, 52 | sides of 5 |
| 61, 62 | levels of 6 |
| 71 | rotatable substrate holder |
| 72, 73 | rotation axes |
| 75 | carousel |
| 76 | conveyor belt |
| 77 | rollers |
| 80 | PDA |
| 81 | display panel |
| 90 | antenna |
| 91 | tuning unit |
| 92 | generator |
| 131 | sputter magnetron |
| 132 | arc discharge suppression |
| 133 | power supply unit |
| 134 | screen device |
| 151 | high vacuum pump apparatus |
| 152 | fine vacuum pump apparatus |
| 153 | pressure regulator |
| 154, 155 | connections of 15 to 3 |
| 156 | valve |
| 160 | pre-pressure pump apparatus |
| 171 | gas inlet |
| 600 | adhesion promoter layer |
| 601 | indium tin oxide layer |
| 602 | multilevel antireflection layer |
| 603 | scratchproof layer |
| 604 | spacer layer |

1. A device for the vacuum coating of substrates which comprises a vacuum chamber, an apparatus for holding at least one substrate, at least one first coating region of the vacuum chamber with an apparatus for plasma pulse-induced chemical vapor deposition (PICVD) and at least one second coating region of the vacuum chamber with at least one apparatus for sputter coating, as well as a transport apparatus for transporting the substrate into the coating regions, which device has a screen device for screening the sputter target.

2. The device as claimed in claim 1, having a transport apparatus for simultaneously transporting a plurality of substrates.

3. The device as claimed in claim 1, wherein the apparatus for sputter coating comprises an apparatus for reactive sputtering.

4. The device as claimed in claim 1, having an apparatus for generating a plasma containing one of nitrogen and oxygen.

5. The device as claimed in claim 4, wherein the apparatus for plasma pulse-induced chemical vapor deposition comprises a plasma containing one of nitrogen and oxygen.

6. The device as claimed in claim 1, wherein the transport apparatus comprises at least one apparatus for rotating the substrate.

7. The device as claimed in claim 6, wherein the transport apparatus comprises an apparatus for rotating the substrate about a plurality of axes.

8. The device as claimed in claim 1, wherein the transport apparatus comprises an apparatus for linear movement of the substrate.

9. The device as claimed in claim 1, wherein the transport apparatus comprises a conveyor belt.

10. The device as claimed in claim 1, wherein the transport apparatus comprises a plurality of apparatuses, drivable independently of one another, for moving substrates.

11. The device as claimed in claim 1, wherein the transport apparatus comprises a substrate holder which is arranged between opposing apparatuses for plasma pulse-induced chemical vapor deposition (PICVD) and for sputter coating.

12. (canceled)

13. The device as claimed in claim 1, having a plurality of apparatuses for plasma pulse-induced chemical vapor deposition (PICVD).

14. The device as claimed in claim 1, having a plurality of apparatuses for sputter coating.

15. The device as claimed in claim 1, having coating regions arranged along the circumferential direction of a circular section of the conveyor belt of the transport apparatus.

16. The device as claimed in claim 11, wherein at least one of (i) the apparatuses for plasma pulse-induced chemical vapor deposition (PICVD) and (ii) the apparatuses for sputter coating is arranged along at least one linear section of the conveyor belt of the transport apparatus.

17. The device as claimed in claim 1, having a pump apparatus with a plurality of connections to the vacuum chamber.

18. The device as claimed in claim 17, wherein a connection is assigned to each coating region.

19. The device as claimed in claim 1, having an apparatus for applying a coating by evaporation.

20. The device as claimed in claim 1, having an apparatus for electron cyclotron resonance sputtering.

21. The device as claimed in claim 1, having a heating apparatus.

22. A method for the vacuum coating of substrates in which at least one substrate is held in a vacuum chamber, at least one level of a coating is deposited on the substrate by means of plasma pulse-induced chemical vapor deposition (PICVD) in at least one first coating region of the vacuum chamber and at least one level of the coating is deposited by sputtering in a second coating region of the vacuum chamber, and the substrate is transported into the coating regions by means of a transport apparatus, wherein a sputter target is screened by a screen device during one of (i) Plasma pulse-induced chemical vapor deposition and (ii) a cleaning procedure to remove water or an oxide layer on the substrate.

23. The method as claimed in claim 22, wherein the substrate is arranged sequentially in the coating regions by means of the transport apparatus and at least one level of the coating is respectively deposited in the coating regions.

24. The method as claimed in claim 22, wherein a plurality of substrates are arranged on the transport apparatus and coated successively or simultaneously.

25. The method as claimed in claim 22, wherein the substrate is coated by means of reactive sputtering.

26. The method as claimed in claim 22, wherein at least one deposited level of the coating is nitrided or oxidized in the vacuum chamber by means of a plasma containing one of oxygen and nitrogen.

27. The method as claimed in claim 26, wherein one level of a coating is sputtered onto the substrate in at least one first coating region of the vacuum chamber, the substrate is arranged in a second coating region by the transport apparatus and is oxidized or nitrided there by means of a plasma containing one of oxygen and nitrogen.

28. The method as claimed in claim 22, wherein the substrate is rotated by the transport apparatus.

29. The method as claimed in claim 28, wherein the substrate is rotated about a plurality of axes.

30. The method as claimed in claim 22, wherein the substrate is moved during the coating.

31. The method as claimed in claim 22, wherein the movements of a plurality of substrates are driven independently of one another.

32. The method as claimed in claim 22, wherein the substrate is delivered along a circular or linear section of the conveyor belt to the coating regions by the transport apparatus.

33. The method as claimed in claim 22, wherein the substrate is moved by a conveyor belt.

34. (canceled)

35. The method as claimed in claim 22, wherein a plurality of levels of the coating are deposited on the substrate by means of a plurality of apparatuses for plasma pulse-induced chemical vapor deposition (PICVD).

36. The method as claimed in claim 22, wherein a plurality of levels of the coating are deposited on the substrate by means of a plurality of apparatuses for sputter coating.

37. The method as claimed in claim 22, wherein a multi level coating is deposited with levels of different composition.

38. The method as claimed in claim 22, wherein a alternating multi level layer is deposited with alternating composition.

39. The method as claimed in claim 22, wherein an adhesion promoter layer is deposited.

40. The method as claimed in claim 22, wherein a gradient layer is deposited.

41. The method as claimed in claim 22, wherein at least one metallic layer is sputtered.

42. The method as claimed in claim 22, wherein at least one magnetizable layer is sputtered.

43. The method as claimed in claim 22, wherein at least one indium tin oxide layer is deposited.

44. The method as claimed in claim 22, wherein at least one level of the layer is deposited by means of electron cyclotron resonance sputtering.

45. The method as claimed in claim 22, wherein a plurality of substrates are coated in parallel or sequentially with at least one level of the coating.

46. The method as claimed in claim 22, wherein at least parts of the vacuum chamber or the substrate are heated.

47. The method as claimed in claim 22, wherein the substrate surface is activated or cleaned by means of a plasma.

48. The method as claimed in claim 22, wherein a layer which contains zirconium and niobium or tantalum is sputtered on.

49. A display panel having at least one substrate coated in accordance with the method of claim 22.

50. The display panel as claimed in claim 49, wherein the substrate comprises a coating with
an adhesion promoter layer,
an indium tin oxide layer,
a multi level anti reflection layer, and
a scratch proof layer.

51. A lamp reflector coated in accordance with the method of claim 22.

52. An optical interference filter having a multilevel interference layer produced in accordance with the method of claim 22.
